(19) United States
(12) Patent Application Publication
(10) Pub. No.: US 2004/0174678 A1
(43) Pub. Date: Sep. 9, 2004

(54) Cooling element for high temperature devices

(75) Inventor: Takahiro Kojima, Mishima-shi (JP)

Correspondence Address: FOLEY AND LARDNER, SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 10/382,100

(22) Filed: Mar. 6, 2003

(51) Int. Cl. H05K 7/20

(52) U.S. Cl. 361/697

(57) ABSTRACT

A cooling element for cooling an electronic device in an apparatus includes a cover portion configured to cover the device, the cover portion having a top surface. A plurality of fins are positioned on the top surface of the cover portion. Each of the plurality of cooling fins are substantially parallel to each other, and each of the plurality of cooling fins has a middle portion wider than each end portion.

### FIELD OF THE INVENTION

The present invention relates generally to cooling elements and, more particularly, to a cooling element design for cooling high temperature devices, such as in an image processing device.

### BACKGROUND OF THE INVENTION

During the operation of an electronic device, such as an image forming apparatus, elements of the device may become very hot. Some of these elements can be heat sensitive, such that their operation and performance deteriorates in the event that they become too hot. To avoid this overheating, the electronic device can include cooling elements to cool the heat-affected elements and maintain their operation and performance.

FIGS. 1A-1D show one example of a cooling element as disclosed by U.S. Pat. No. 5,576,932 to Bishop et al. FIGS. 1A and 1B, respectively show a top view and a side view of a cooling element 214. The cooling element 214 includes a plurality of fins 222. The fins 222 have a rectangular shape, and each pair of fins 222 defines a channel 224 there between. The bottom of the cooling element 214 defines a mating surface 226 by which the cooling element 214 attaches to an element to be cooled, such as an integrated circuit device. In addition to the rectangular shape, the fins 222 can be shaped in a decreasingly tapered manner as shown in FIG. 1C or in an increasingly tapered manner as shown in FIG. 1D.

In each of the designs shown in FIGS. 1A-1D, the fins 222 have a uniform cross section from one end to the other (such as shown by the constant width across each fin 222). With this uniform cross section, the air flow through the channels 224 is relatively constant. It would be desirable to have fin designs that would provide increased air flow, which would improve the cooling effect of the cooling element.

### SUMMARY OF THE INVENTION

According to one aspect of the invention, a cooling element for cooling an electronic device in an apparatus includes a cover portion configured to cover the device, the cover portion having a top surface. A plurality of cooling fins are positioned on the top surface of the cover portion. Each of the plurality of cooling fins are substantially parallel to each other, and each of the plurality of cooling fins has a middle portion wider than each end portion.

### BRIEF DESCRIPTION OF THE DRAWINGS

FIGS. 1A-1D are top and side views of a conventional cooling element.

FIG. 2 is a block diagram of an image forming apparatus consistent with the present invention.

FIG. 3 is a block diagram of a control system for the image forming apparatus of FIG. 2.

FIGS. 4A and 4B are side and top views, respectively, of a cooling element consistent with the present invention.

FIG. 5 is a perspective view of the cooling element of FIGS. 4A and 4B.

FIGS. 6A and 6B are side and top views, respectively, of another cooling element consistent with the present invention.

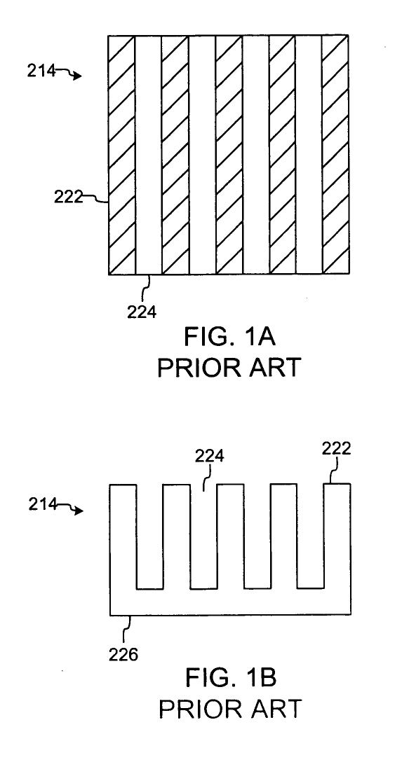

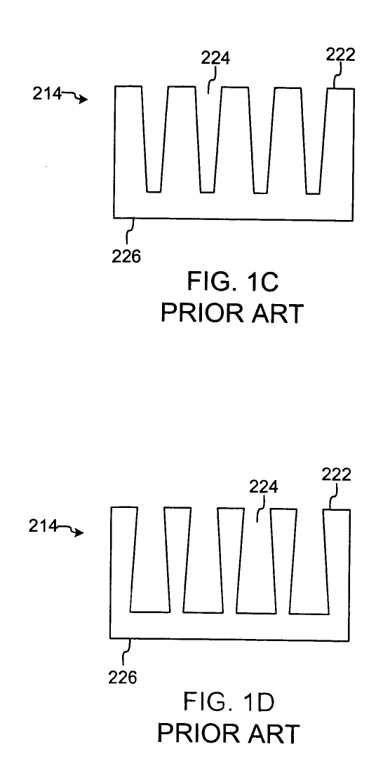

### DETAILED DESCRIPTION OF THE PREFERRED EMBODIMENT

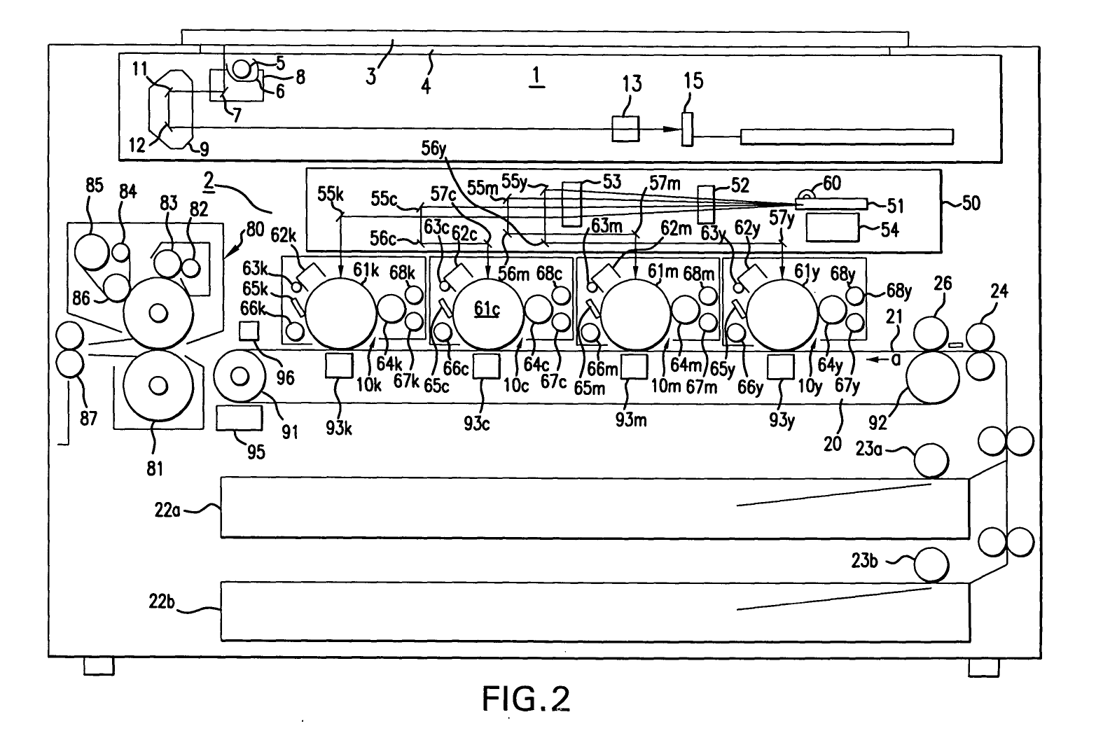

FIG. 2 shows a block diagram of an image forming apparatus consistent with the present invention. The image forming apparatus may be a hardcopy device such as a digital type color copier for forming a copied image of a color image. As shown in FIG. 2, the image forming apparatus includes a color scanner portion 1, which scans and reads a color image on a document and a color printer portion 2, which forms a copied image of the color image. The image forming apparatus could alternatively be a black and white image processor.

In the case of the color copier, the color scanner portion 1 includes a document base cover 3 at an upper portion thereof. A document base 4 is arranged opposite to the document base cover 3 in a closed state and includes transparent glass on which the document is set. On a lower side of the document base 4 are arranged an exposure lamp 5 for illuminating the document mounted on the document base 4, a reflector 6 for focusing light from the exposure lamp 5 to the document, and a first mirror 7 for reflecting the light from the document. The exposure lamp 5, the reflector 6 and the first mirror 7 are fixed to a first carriage 8. The first carriage 8 is moved by a pulse motor, not illustrated, along a lower face of the document base 4.

A second carriage 9 is arranged in a direction in which the light is reflected by the first mirror 7 and provided movably in parallel with the document base 4 via a drive mechanism, such as a belt with teeth in conjunction with a direct current motor or the like. The second carriage 9 includes a second mirror 11 for reflecting the light from the first mirror 7 to a third mirror 12. The third mirror 12 then reflects the light from the second mirror 11. The second carriage 9 is driven by the first carriage 8 and is moved along the document base 4 in parallel therewith at half the speed of the first carriage 8.

A focusing lens 13 focuses the light reflected from the third mirror 12 by a predetermined magnification. A CCD type color image sensor or photoelectric conversion element 15 converts the reflected light focused by the focusing lens 13 into an electric signal.

When light from the exposure lamp 5 is focused on the document on the document base 4 by the reflector 6, the reflected light from the document is made to be incident on the color image sensor 15 via the first mirror 7, the second mirror 11, the third mirror 12 and the focusing lens 13. At the color image sensor 15, the incident light is converted into an electric signal in accordance with the three primary colors of light of R (red), G (green) and B (blue).

The color printer portion 2 includes first through fourth image forming portions 10y, 10m, 10c and 10k. These image forming portions form images that are subjected to color decomposition for respective color components. In particular, the images are decomposed into the four colors of yellow (y), magenta (m), cyan (c) and black (k) according to known decomposition methods, such as the subtractive mixing method.

A transfer mechanism 20, which includes a transfer belt 21, transfers the images of the respective colors formed by the respective image forming portions in a direction shown by the arrow marked “a” in FIG. 2. The transfer belt 21 is wound to expand between a drive roller 91 rotated by a motor in the direction shown by the arrow marked “a,” and a drive roller 92 separated from the drive roller 91 by a predetermined distance rotating at a constant speed in the direction of the arrow marked “a.” The image forming portions 10y, 10m, 10c and 10k are arranged in series along a transfer direction of the transfer belt 21.

The image forming portions 10y, 10m, 10c and 10k include photosensitive drums 61y, 61m, 61c and 61k, respectively, as image carriers. Outer peripheral faces of the drums are formed in the same direction at respective positions in contact with the transfer belt 21. The photosensitive drums 61y, 61m, 61c and 61k are rotated at a predetermined speed by a motor.

The photosensitive drums 61y, 61m and 61c and 61k are arranged such that their axis lines are respectively disposed at equal intervals and are arranged such that the axis lines are orthogonal to the direction that the images are transferred by the transfer belt 21. The directions of the axis lines of the photosensitive drums 61y, 61m, 61c and 61k are defined as main scanning directions. The rotational directions of the photosensitive drums 61y, 61m, 61c and 61k, which correspond to a rotational direction of the transfer belt 21 (the arrow marked “a”), are defined as subscanning directions.

Electricity charging apparatus 62y, 62m, 62c and 62k, electricity removing apparatus 63y, 63m, 63c and 63k and developing rollers 64y, 64m, 64c and 64k are all extended in the main scanning direction. Lower agitating rollers 67y, 67m, 67c and 67k, upper agitating rollers 68y, 68m, 68c and 68k, transcribing apparatus 93y, 93m, 93c and 93k, and cleaning blades 65y, 65m, 65c and 65k also extend in the main scanning direction. Discharged toner recovery screws 66y, 66m, 66c and 66k are arranged successively along the rotational direction of the photosensitive drums 61y, 61m, 61c and 61k.

Transcribing apparatus 93y, 93m, 93c and 93k are arranged at positions sandwiching the transfer belt 21 between them. Corresponding ones of the photosensitive drums 61y, 61m, 61c and 61k are arranged on an inner side of the transfer belt. Further, exposure points by an exposure apparatus 50 are respectively formed on the outer peripheral faces of the photosensitive drums 61y, 61m, 61c and 61k between the electricity charging apparatus 62y, 62m, 62c and 62k and developing rollers 64y, 64m, 64c and 64k.

Sheet cassettes 22a and 22b are arranged on a lower side of the transfer mechanism 20 and contain sheets of the sheet P as image forming media for transcribing images formed by the respective image forming portions 10y, 10m, 10c and 10k. Pickup rollers 23a and 23b are arranged at end portions on one side of the sheet cassettes 22a and 22b and on sides thereof proximate to the drive roller 92. Pickup rollers 23a and 23b pick up the sheet P contained in the sheet cassettes 22a and 22b sheet by sheet from topmost portions of the sheets. A register roller 24 is arranged between the pickup rollers 23a and 23b and the drive roller 92. The register roller 24 matches a front end of the sheet P picked from the sheet cassette 22a or 22b and a front end of a toner image formed at the photosensitive drum 61y of the image forming portion 10y. Toner images formed at the other photosensitive drums 61y, 61m and 61c are supplied to respective transcribing positions in conformity with transfer timings of the sheet P transferred on the transfer belt 21.

An adsorbing roller 26 is arranged between the register roller 24 and the first image forming portion 10y, at a vicinity of the drive roller 92, such as above an outer periphery of the drive roller 92 substantially pinching the transfer belt 21. The adsorbing roller 26 provides electrostatic adsorbing force to the sheet P transferred at predetermined timings via the register roller 24. The axis line of the adsorbing roller 26 and the axis line of the drive roller 92 are set to be in parallel with each other.

A positional shift sensor 96 is arranged at one end of the transfer belt 21, and at a vicinity of the drive roller 91, such as above an outer periphery of the drive roller 91 substantially pinching the transfer belt 21. The positional shift sensor 96 detects a position of the image formed on the transfer belt 21. The positional shift sensor 96 may be implemented, for example, as a transmitting type or a reflecting type optical sensor.

A transfer belt cleaning apparatus 95 is arranged on an outer periphery of the drive roller 91 and above the transfer belt 21 on the downstream side of the positional shift sensor 96. The transfer belt cleaning apparatus 95 removes toner or paper dust off the sheet P adhered onto the transfer belt 21.

A fixing apparatus 80 is arranged to receive the sheet P when it detaches from the transfer belt 21 and transfers the sheet P further. The fixing apparatus 80 fixes the toner image on the sheet P by melting the toner image transcribed onto the sheet P by heating the sheet P to a predetermined temperature. The fixing apparatus 80 includes a pair of heat rollers 81, oil coating rollers 82 and 83, a web winding roller 84, a web roller 85 and a web pressing roller 86. After the toner formed on the sheet P is fixed to the sheet, the sheet P is discharged by a paper discharge roller pair 87.

The exposure apparatus 50 forms electrostatic latent images subjected to color decomposition on the outer peripheral faces of the photosensitive drums 61y, 61m, 61c and 61k. The exposure apparatus is provided with a semiconductor laser oscillator 60 controlled to emit light based on image data (Y, M, C, K) for respective colors subjected to color decomposition by an image processing portion 36.

On an optical path of the semiconductor laser oscillator 60, there are successively provided a polygonal mirror 51 rotated by a polygonal motor 54 for reflecting and scanning a laser beam light and fθ lenses 52 and 53 for correcting and focusing a focal point of the laser beam light reflected via the polygonal mirror 51. First folding mirrors 55y, 55m, 55c and 55k are arranged between the fθ lens 53 and the photosensitive drums 61y, 61m, 61c and 61k. The first folding mirrors 55y, 55m, 55c and 55k fold or reflect the laser beam light of respective colors that have passed through the fθ lens 53 toward the exposure positions of the photosensitive drums 61y, 61m, 61c and 61k. Second and third folding mirrors 56y, 56m, 56c and 57y, 57m and 57c further fold or reflect the laser beam light folded by the first folding mirrors 55y, 55m and 55c. The laser beam light for black is folded or reflected by the first folding mirror 55k and thereafter guided onto the photosensitive drum 61k without detouring other mirrors.

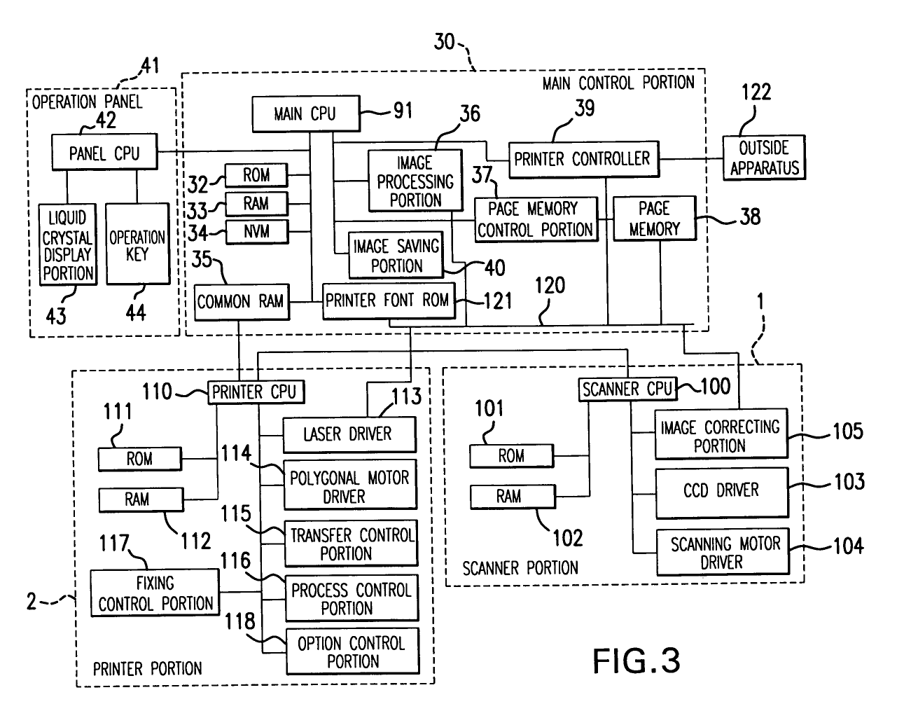

FIG. 3 shows a block diagram of a control system for the image forming apparatus of FIG. 2. In FIG. 3, the control system includes three CPUs: a main CPU (Central Processing Unit) 91 in a main control portion 30; a scanner CPU 100 of the color scanner portion 1; and a printer CPU 110 of the color printer portion 2. The main CPU 91 carries out bidirectional communication with the printer CPU 110 via a common RAM (Random Access Memory) 35. The main CPU 91 issues operation instructions, and the printer CPU 110 returns state statuses. The printer CPU 110 and the scanner CPU 100 carry out serial communication. The printer CPU 110 issues operation instructions, and the scanner CPU 100 returns state statuses.

An operation panel 41 includes a liquid crystal display portion 43, various operation keys 44 and a panel CPU 42. The operation panel 41 is connected to the main CPU 91. The main control portion 30 includes the main CPU 91, a ROM (Read Only Memory) 32, a RAM 33, an NVRAM 34, the common RAM 35, the image processing portion 36, a page memory control portion 37, a page memory 38, a printer controller 39 and a printer font ROM 121.

The main CPU 91 controls the main control portion 30. The ROM 32 is stored with control programs. The RAM 33 is for temporarily storing data. The NVRAM (Nonvolatile Random Access Memory or Nonvolatile RAM 34 is a memory backed up with a battery (not illustrated) for holding stored data even when a power source is cut. The common RAM 35 is for carrying out bidirectional communication between the main CPU 91 and the printer CPU 110.

The page memory control portion 37 stores and reads image information to and from the page memory 38. The page memory 38 includes an area capable of storing a plurality of pages of image information and is formed to be able to store data compressed with image information from the color scanner portion 1 for each compressed page.

The printer font ROM 121 is stored with font data in correspondence with the print data. The printer controller 39 develops printer data from an outside apparatus 122, such as a personal computer, into image data. The printer controller uses the font data stored in the printer font ROM 121 at a resolution in accordance with data indicating a resolution included in the printer data.

The color scanner portion 1 includes the scanner CPU 100, which controls the color scanner portion 1. The color scanner portion also includes a ROM 101 stored with control programs, a RAM 102 for storing data, a CCD driver 103 for driving the color image sensor 15, a scanning motor driver 104 for controlling rotation of a scanning motor and moving the first carriage 8, and an image correcting portion 105. The image correcting portion 105 includes an A/D conversion circuit for converting analog signals of R, G and B outputted from the color image sensor 15 respectively into digital signals, a shading correction circuit for correcting a dispersion in a threshold level with respect to an output signal from the color image sensor 15 caused by a variation in the color image sensor 15 or surrounding temperature change, and a line memory for temporarily storing the digital signals subjected to shading correction from the shading correction circuit.

The color printer portion 2 includes the printer CPU 110, which controls the color printer portion 2. The color printer portion 2 also includes a ROM 111 stored with control programs, a RAM 112 for storing data, the laser driver 113 for driving the semiconductor laser oscillator 60, a polygonal motor driver 114 for driving the polygonal motor 54 of the exposure apparatus 50, and a transfer control portion 115 for controlling the transfer of the sheet P by the transfer mechanism 20.

The color printer portion 2 further includes a process control portion 116, a fixing control portion 117 for controlling the fixing apparatus 80, and an option control portion 118 for controlling options. The process control portion 116 controls processes for charging electricity, developing and transcribing by use of the electricity charging apparatus, the developing roller and the transcribing apparatus. The image processing portion 36, the page memory 38, the printer controller 39, the image correcting portion 105 and the laser driver 113 are connected to each other by an image data bus 120.

The foregoing is just one example of an image processing device, which is further just one example of an electronic device to which the present invention can be applied. The present invention is not necessarily limited in it potential application to any particular kind of electronic device.

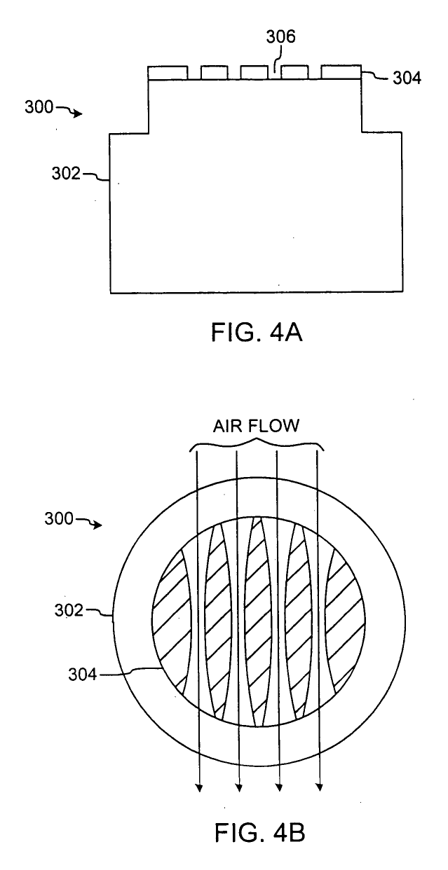

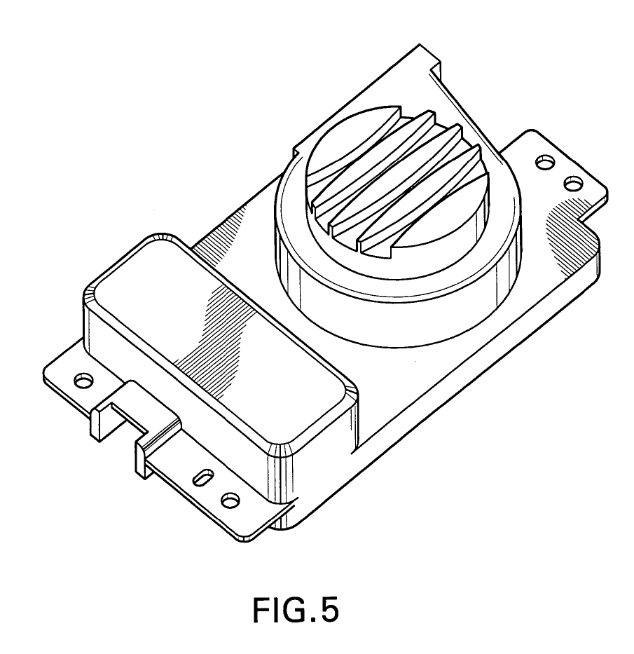

FIGS. 4A and 4B are side and top views, respectively, of a cooling element consistent with the present invention. FIG. 5 is a perspective view of the cooling element of FIGS. 4A and 4B. As shown in FIGS. 4A and 4B, a cooling element 300 includes a cover portion 302 and a plurality of fins 304 on, and extending from, a top surface of the cover portion 302. The space between adjacent fins 304 define a plurality of channels 306. The cover portion 302 as shown has a step, such that it has a wider base that a top portion, but any shape (such as constant width) is possible. The fins 304 can span across the entire cover portion 302 or be shorter than the overall width of the cover portion 302.

The cover portion 302 and the plurality of fins 304 are preferably formed with a heat conductive material, such as aluminum or copper. The cover portion 302 is preferably shaped to substantially conform to the outer shape of a device being cooled. The device being cooled can be an element of an image forming apparatus, such as the image forming apparatus shown in FIG. 2. The element of the image forming apparatus being cooled can be, for example, a laser or a motor. For example, the device being cooled can be the laser 60 or the motor 54, as shown in FIG. 2. The device being cooled can also be part of a different apparatus, such as a computer, video equipment, audio equipment or any other apparatus having a device where cooling is needed to avoid overheating and deterioration of performance. The spacing between the cooling element 302 and the device being cooled is preferably kept to a minimum, such as about 2 mm. In addition, the thickness of the cover portion 302 is preferably about 2-3 mm.

As shown in FIG. 4A, the fins 304 in their longitudinal direction are substantially parallel to each other. As shown in FIG. 4B, however, the cross-section of the fins 304 is not uniform. Rather, each fin 304 has a relatively wide central, or middle, portion and relatively narrow end portions. There is preferably a smooth transition between the wider central portion and the narrower end portions. The shape of each fin 304 can be symmetrical, such as shown in FIG. 4B. Alternatively, the shape can be asymmetrical, like the shape of a wing or an airfoil.

As can be seen in FIG. 4B, air flows through the channels 306 between adjacent fins 304. The narrower end portions of the fins 304 create larger openings for each channel 306. The larger openings thereby provide a larger volume of air to flow into the channels 306. Correspondingly, the wider central portions of the fins 304 create narrower spaces in the central portions of the channels 306. Since the volume of air entering the channels 306 equals the volume of air exiting the channels 306, the flow rate of the air through the narrower central portions of the channels 306 is increased. The larger volume of air entering the channels 306 and the increased flow rate through the central portions of the channels 306 results in improved cooling of the device being cooled by the cooling element 300.

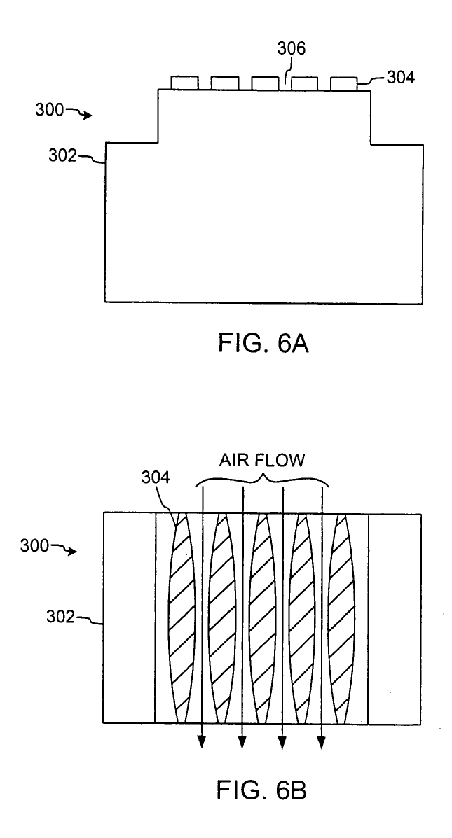

FIGS. 6A and 6B are side and top views, respectively, of another cooling element consistent with the present invention. As shown in FIGS. 6A and 6B, the cooling element 300 also includes a cover portion 302, a plurality of fins 304 and channels 306 defined by adjacent pairs of the fins 304. The shape of the cover portion 302 in FIGS. 6A and 6B has a substantially square or rectangular shape. The cover portion 302 can be other shapes beyond circular or square, such as triangular, hexagonal, irregularly shaped, or other shape as understood by one skilled in the art, and as desired depending on the part being cooled.

The cooling effect provided by the cooling element 300 of FIGS. 6A and 6B is substantially similar to the cooling effect of the cooling element 300 of FIGS. 4A and 4B. As shown in FIG. 6B, the fins 304 also have wider central portions and narrower end portions. As a result of this shape, a larger volume of air can enter the channels 306 and a flow rate through the central portions of the channels 306 increases, which results in improved cooling of the device being cooled by the cooling element 300 of FIGS. 6A and 6B.

Yet another alternative for the shape of the fins 304 is that the outer end portions of selected fins 304 could be wider than the middle portions, or any combination of non-uniform widths of the foregoing, such as one fin 304 having a relatively wider central portion than the ends, and another fin 304 having a wider end portion or portions than the central portion. The different fins 304 may be adjacent to one another or in separate groups. Also, in any of the disclosed embodiments, the fins 304 can have a constant rectangular shape, or increasing or decreasing tapered shapes as extending from the surface of the cover portion 302.

The foregoing description of a preferred embodiment of the invention has been presented for purposes of illustration and description. It is not intended to be exhaustive or to limit the invention to the precise form disclosed, and modifications and variations are possible in light in the above teachings or may be acquired from practice of the invention. The embodiments were chosen and described in order to explain the principles of the invention and as practical application to enable one skilled in the art to utilize the invention in various embodiments and with various modifications are suited to the particular use contemplated. It is intended that the scope of the invention be defined by the claims appended hereto and their equivalents.

What is claimed is:

1. A cooling element for cooling an electronic device in an apparatus, comprising:
a cover portion configured to cover at least a portion of the device, the cover portion having a top surface;
a plurality of cooling fins positioned on the top surface of the cover portion, each of the plurality of cooling fins being substantially parallel to each other, and
wherein each of the plurality of cooling fins has a middle portion wider than each end portion.

2. A cooling element according to claim 1, wherein the cover portion is substantially shaped to correspond to an outer shape of the device.

3. A cooling element according to claim 1, wherein at least two of the plurality of cooling fins have an airfoil shape.

4. A cooling element according to claim 1, wherein at least two of the plurality of cooling fins of the cooling element are tapered from the middle portion to the end portions.

5. A cooling element according to claim 1, wherein at least two of the plurality of cooling fins of the cooling element have a curved shape from the middle portion to the end portions.

6. A cooling element according to claim 1, wherein at least two of the plurality of cooling fins of the cooling element are shorter than a top surface of the cover portion.

7. A cooling element according to claim 1, wherein the shape of the cover portion is circular.

8. A cooling element according to claim 1, wherein the shape of the cover portion is either rectangular or square.

9. A cooling element according to claim 1, wherein the cooling element comprises aluminum.

10. A cooling element according to claim 1, wherein the shape of the cover portion is designed to provide a space of about 2 mm between the outer surface of the device and the cover portion.

11. A cooling element according to claim 1, wherein a thickness of the cover portion is about 2 to 3 mm.

12. An image forming apparatus, comprising:
a scanner portion that scans and reads an image on a document;
a printer portion that forms a copied image of the scanned image from the scanner portion, one of the scanner portion and the printer portion having a device for cooling; and
a cooling element having a cover portion configured to cover the device, the cover portion having a top surface, and a plurality of cooling fins positioned on the top surface of the cover portion, each of the plurality of cooling fins being substantially parallel to each other, and
wherein each of the plurality of cooling fins has a middle portion wider than each end portion.

13. An image forming apparatus according to claim 12, wherein the cover portion is substantially shaped to correspond to an outer shape of the device.

14. An image forming apparatus according to claim 12, wherein at least two of the plurality of cooling fins of the cooling element have an airfoil shape.

15. An image forming apparatus according to claim 12, wherein at least two of the plurality of cooling fins of the cooling element are tapered from the middle portion to the end portions.

16. An image forming apparatus according to claim 12, wherein at least two of the plurality of cooling fins of the cooling element have a curved shape from the middle portion to the end portions.

17. An image forming apparatus according to claim 12, wherein at least two of the plurality of cooling fins of the cooling element are shorter than a top surface of the cover portion.

18. An image forming apparatus according to claim 12, wherein the shape of the cover portion of the cooling element is circular.

19. An image forming apparatus according to claim 12, wherein the shape of the cover portion is either rectangular or square.

20. An image forming apparatus according to claim 12, wherein the cooling element comprises aluminum.

21. An image forming apparatus according to claim 12, wherein the shape of the cover portion is designed to provide a space of about 2 mm between the outer surface of the device and the cover portion.

22. An image forming apparatus according to claim 12, wherein a thickness of the cover portion is about 2 to 3 mm.

23. An image forming apparatus according to claim 12, wherein the device is a laser.

24. An image forming apparatus according to claim 12, wherein the device is a motor.

25. A cooling element for cooling an electronic device in an apparatus, comprising:
a cover portion configured to cover at least a portion of the device, the cover portion having a top surface;
a plurality of cooling fins positioned on the top surface of the cover portion, each of the plurality of cooling fins being substantially parallel to each other, and
wherein a width of a middle portion of each of the plurality of cooling fins varies from a width of each end portion of each of the plurality of cooling fins.

26. A cooling element according to claim 25, wherein the cover portion is substantially shaped to correspond to an outer shape of the device.

27. A cooling element according to claim 25, wherein at least two of the plurality of cooling fins have an airfoil shape.

28. A cooling element according to claim 25, wherein at least two of the plurality of cooling fins of the cooling element are tapered from the middle portion to the end portions.

29. A cooling element according to claim 25, wherein at least two of the plurality of cooling fins of the cooling element have a curved shape from the middle portion to the end portions.

30. A cooling element according to claim 25, wherein at least two of the plurality of cooling fins of the cooling element are shorter than a top surface of the cover portion.

31. A cooling element according to claim 25, wherein the shape of the cover portion is circular.

32. A cooling element according to claim 25, wherein the shape of the cover portion is either rectangular or square.

33. A cooling element according to claim 25, Wherein the cooling element comprises aluminum.

34. A cooling element according to claim 25, wherein the shape of the cover portion is designed to provide a space of about 2 mm between the outer surface of the device and the cover portion.

35. A cooling element according to claim 25, wherein a thickness of the cover portion is about 2 to 3 mm.

36. A cooling element for cooling an electronic device in an apparatus, comprising:
a cover portion configured to cover at least a portion of the device, the cover portion having a top surface;
a plurality of cooling fins positioned on the top surface of the cover portion, each of the plurality of cooling fins being substantially parallel to each other, and
wherein each of the plurality of cooling fins has a non-uniform cross-sectional width.

37. The cooling element of claim 36, wherein at least two of the plurality of cooling fins have a different cross-section from each other.

38. The cooling element of claim 36, wherein the plurality of cooling fins are tapered along a height of the plurality of cooling fins as extending from the cover portion.

39. An image forming apparatus comprises at least one cooling element as claimed in claim 36.
